(19) United States
(12) Patent Application Publication
(10) Pub. No.: US 2014/0321151 A1
(43) Pub. Date: Oct. 30, 2014

(54) ILLUMINATION APPARATUS, VEHICLE HEADLAMP, AND DOWNLIGHT

(71) Applicant: SHARP KABUSHIKI KAISHA, Osaka-shi, Osaka (JP)

(72) Inventors: Rina Sato, Osaka-shi (JP); Katsuhiko Kishimoto, Osaka-shi (JP)

(73) Assignee: Sharp Kabushiki Kaisha, Osaka-shi, Osaka (JP)

(21) Appl. No.: 14/359,057

(22) PCT Filed: Nov. 19, 2012
(86) PCT No.: PCT/JP2012/079990

§ 371 Date: May 16, 2014

(30) Foreign Application Priority Data
Nov. 18, 2011 (JP) 2011-253191

(51) Int. Cl. F21K 99/00; H01S 5/30; F21V 29/00; F21S 8/10; H01S 5/022

(52) U.S. Cl. CPC F21K 9/56; F21K 9/52; F21S 48/1131; H01S 5/02284; F21K 9/50; F21V 29/004; F21S 48/1145; H01S 5/3013
USPC 362/553; 362/544; 362/84; 362/231

(57) ABSTRACT

A headlamp includes a plurality of laser devices that emit laser light and a light emitting section that generates light upon receiving light. The laser light sources generate laser light of a plurality of wavelengths different from one another and each generate laser light of a wavelength that causes the light emitting section to generate light, and the one light emitting section is irradiated with laser light from the plurality of laser light sources.

### CROSS-REFERENCE TO RELATED APPLICATIONS

This application is a national phase filing under 35 U.S.C. §371 of International Application No. PCT/JP2012/079990, filed on Nov. 19, 2012, which claims priority to Japanese Patent Application No. 2011-253191, filed on Nov. 18, 2011, the contents of which prior applications are incorporated herein by reference.

### FIELD OF THE INVENTION

The present invention relates to an illumination apparatus, vehicle headlamp, and downlight capable of emitting illumination light of varying chromaticity without changing the position of a luminous point.

### BACKGROUND OF THE INVENTION

There have been active researches on light emitting apparatuses that use a semiconductor light emitting device such as an light emitting diode (LED) or laser diode (LD) as the excitation light source and apply excitation light generated by the excitation light source to a light emitting section containing phosphors to generate illumination light.

An example of techniques relating to such light emitting apparatuses is disclosed by PTL 1.

The light emitting apparatus disclosed by PTL 1 uses a GaN-based semiconductor laser that emits laser light having a wavelength of 450 nm or less as the excitation light source and combines the laser with a phosphor that is excited with laser light to emit fluorescent light in the visible range. The light emitting apparatus excites the phosphor with light having a short wavelength of 450 nm or less, such as blue or ultraviolet light, thereby achieving generation of high-intensity light.

### Patent Literature

PTL 1: Japanese Unexamined Patent Application Publication No. 2000-174346 (published on Jun. 23, 2000)

PTL 2: Japanese Unexamined Patent Application Publication No. 2005-150041 (published on Jun. 9, 2005)

PTL 3: Japanese Unexamined Patent Application Publication No. 2004-354495 (published on Dec. 16, 2004)

PTL 4: Japanese Unexamined Patent Application Publication No. 2012-121968 (published on Jun. 28, 2012)

### SUMMARY OF THE INVENTION

Existing techniques including the light emitting apparatus of PTL 1 however has the following challenge.

LEDs have become smaller and capable of higher output power, and increasingly advanced features are demanded from them. For instance, there is a demand for a device that can control light from a low color temperature to a high color temperature with a single LED bulb for improving quality of life and such devices have already been commercialized.

Such dimming control can be achieved by a mechanism that varies the output power of at least two light sources having different chromaticities. In this scheme, there are luminous points as many as the number of light sources; that is, multiple luminous points are present. Accordingly, incorporation of plural luminous points into an optical system such as a reflector or a lens requires complex optical design because of change in the luminous point positions or presence of the multiple luminous points. Moreover, when a high efficiency optical system is to be realized, the optical system inevitably becomes large in size.

Also, none of PTLs 1 to 4 discloses or implies a configuration in which multiple semiconductor lasers output light of different wavelengths.

The present invention has been made as a solution to the problems, and an object thereof is to provide an illumination apparatus, vehicle headlamp, and downlight capable of emitting illumination light of varying chromaticity without changing the position of a luminous point.

To attain the object, an illumination apparatus according to an embodiment of the invention includes a plurality of laser light sources that emit laser light, and a light emitting section that generates light upon receiving light, wherein the plurality of laser light sources generate laser light of a plurality of wavelengths different from one another and each generate laser light of a wavelength that causes the light emitting section to generate light, and the one light emitting section is irradiated with laser light from the plurality of laser light sources.

The inventive illumination apparatus includes a plurality of laser light sources that emit laser light, and a light emitting section that generates light upon receiving light, wherein the plurality of laser light sources generate laser light of a plurality of wavelengths different from one another and each generate laser light of a wavelength that causes the light emitting section to generate light, and the one light emitting section is irradiated with laser light from the plurality of laser light sources.

The illumination apparatus therefore has the advantage of being able to emit illumination light of varying chromaticity without changing the luminous point position.

### BRIEF DESCRIPTION OF THE DRAWINGS

FIG. 1 generally shows the structure of a headlamp in an embodiment of the invention.

FIG. 2 is a conceptual illustration of the paraboloid of revolution of a parabolic mirror.

FIG. 3(a) is a top view of the parabolic mirror; FIG. 3(b) is a front view of the parabolic mirror; and FIG. 3(c) is a side view of the parabolic mirror.

FIG. 4 generally shows an exemplary structure of the headlamp according to an embodiment of the invention.

FIG. 5 illustrates another example which uses the structure of FIG. 4 in a transmissive headlamp.

FIG. 6 generally shows another exemplary structure of the headlamp according to an alternative embodiment of the invention.

FIG. 7 illustrates another example which uses the structure of FIG. 6 in a transmissive headlamp.

FIG. 8 schematically illustrates the orientation in which the headlamp is installed on an automobile.

FIG. 9 is a chromaticity diagram for demonstrating the effects provided by the headlamp according to the embodiments.

FIG. 10 is a cross-sectional view generally showing the structure of the headlamp in another embodiment of the invention.

FIG. 11 illustrates the positional relation of a light emitting section and an optical fiber exit end included in a headlamp according to the embodiment of the invention.

FIG. 12 schematically illustrates the appearances of a light emitting unit included in a laser downlight according to an embodiment of the invention and a traditional LED downlight.

FIG. 13 is a cross-sectional view of a ceiling with the laser downlight installed therein.

FIG. 14 is a cross-sectional view of the laser downlight.

FIG. 15 is a cross-sectional view showing an alternative installation of the laser downlight.

FIG. 16 is a cross-sectional view of a ceiling with the LED downlight installed therein.

FIG. 17 is a table for comparing the specifications of the laser downlight and the LED downlight.

FIG. 18(a) is a circuit diagram of an exemplary laser light source (LD) for a light emitting apparatus; and FIG. 18(b) schematically illustrates the LD.

### DETAILED DESCRIPTION OF THE INVENTION

A headlamp according to an embodiment of the invention will be described with reference to the drawings. Although the following description mainly discusses a headlamp, a headlamp is merely an example of the illumination apparatus to which the present invention is applicable and it should be appreciated that the invention may be applied to any kind of illumination apparatus. In the following description, the same parts and components are denoted with the same reference characters, and they have the same names and functions. Accordingly, detailed descriptions of such elements will not be repeated.

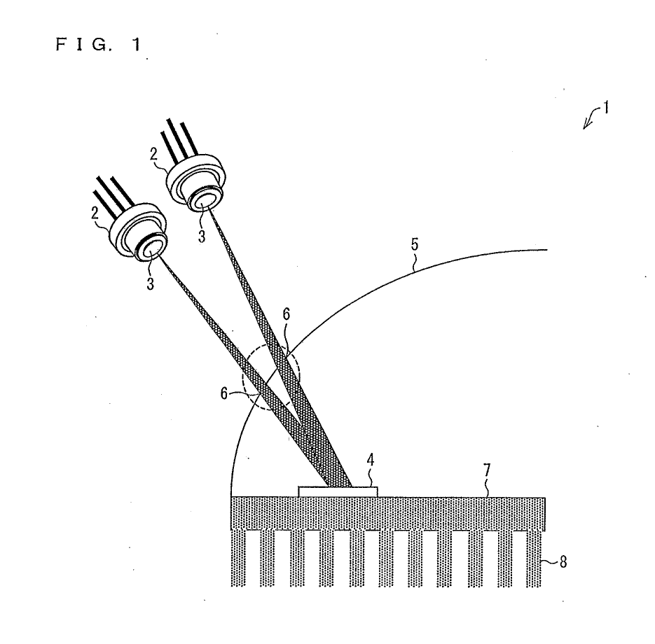

An embodiment of the invention is described below with reference to figures including FIG. 1.

FIG. 1 is a cross-sectional view generally showing the configuration of a headlamp (illumination apparatus) 1 in an embodiment of the invention. As shown in FIG. 1, the headlamp 1 includes laser devices (excitation light sources) 2, lenses 3, a light emitting section 4, a parabolic mirror 5, a metal base 7, and a fin 8.

The laser device 2 is a light emitting device serving as the excitation light source for emitting excitation light. A plurality of laser devices 2 are provided and individually generate laser light serving as excitation light. The laser device 2 may have a single luminous point on one chip or multiple luminous points on one chip.

More specifically, the laser devices 2 include a laser device 2a having a first oscillation wavelength and a laser device 2b having a second oscillation wavelength (the laser devices 2a and 2b may be just referred to as laser device 2 when they are not distinguished). The laser device 2a has an oscillation wavelength in a blue-violet region around 405 nm or a violet to blue-violet region of 400 nm to 420 nm. The laser device 2b has an oscillation wavelength in a range from greater than 450 nm to 530 nm. The headlamp 1 uses the laser device 2a and the laser device 2b to irradiate the single light emitting section 4. The light emitting section 4 contains phosphors that emit fluorescent light with the excitation light emitted from the laser devices 2, and laser light from the laser devices 2 is mixed with the fluorescent light from the phosphor to result in illumination light.

The laser device 2a and the laser device 2b can vary their output power. However, rather than both the laser device 2a and the laser device 2b varying their output power, the output of one of the two may be fixed and the output power of the other may be varied. Such an arrangement eliminates the necessity to adjust the output power of at least the laser device with its output fixed and can reduce the number of laser devices whose output should be controlled, allowing simplification of a program used for the headlamp 1. The headlamp 1 is then capable of adjusting the illumination light to desired chromaticity in a shorter amount of time and also can be reduced in size and weight due to a smaller number of components.

While the laser device 2a and laser device 2b are described as having different oscillation wavelengths, their oscillation wavelengths may be identical or very close to each other. Further, although this feature is not a limitation, both the laser device 2a and the laser device 2b preferably have an output power greater than zero because increasing and decreasing the outputs of the two laser devices can provide diverse changes in chromaticity to the user.

The excitation light source may be light emitting diodes (LEDs) instead of laser devices. The number of laser devices 2 is not limited to two but there may be three or more laser devices 2.

The laser device 2a and the laser device 2b may be in the following relation: the laser device 2a and the laser device 2b contain GaN, InN, and a mixed crystal compound thereof, and have oscillation wavelengths from 400 nm to 420 nm and the difference of their oscillation wavelengths is 10 nm or less.

When the laser devices 2 contain GaN, InN, and a mixed crystal compound thereof and have an oscillation wavelength in the range from 400 nm to 420 nm, the laser devices 2 can have high power conversion efficiency. The headlamp 1 can then provide enhanced luminous efficiency. With the oscillation wavelength of the laser device 2 being in the range from 400 nm to 420 nm, many phosphors are efficiently excited with light in this wavelength range. Phosphors that emit blue light in particular are excited at a high degree of efficiency with light of this wavelength range. For this reason, the total luminous efficiency of the headlamp 1 is increased when the oscillation wavelength of the laser devices 2 is in the range from 400 nm to 420 nm.

The laser device 2a and the laser device 2b may further be in the following relationship: the laser device 2a and the laser device 2b have oscillation wavelengths of greater than 450 nm and 530 nm or less and the difference of their oscillation wavelengths is 10 nm or less.

When the oscillation wavelength of the laser devices 2 is greater than 450 nm and 530 nm or less, the headlamp 1 can make use of light emitted by the laser devices 2 as a blue component in the illumination light emitted by the headlamp 1. Use of a blue color having a longer wavelength in the blue region can increase the safety for retinas of laser light contained in the illumination light emitted by the headlamp 1, according to JIS C6802 (Safety of laser products). Accordingly the emission limit at which eye safety is assured becomes higher than when phosphors are excited with 450-nm laser light, which in turn enables high light output to be set for the laser light which excites phosphors. The headlamp 1 can thereby emit illumination light of higher output power.

It is mentioned above that the difference of the oscillation wavelengths of the laser device 2a and the laser device 2b may be 10 nm or less. This is for the following reason: making multiple laser devices 2 have an identical oscillation wavelength requires precise screening. As laser devices 2 typically have slightly different oscillation wavelengths, preparation of semiconductor lasers with the same oscillation wavelength is very expensive and leads to low yield. By allowing an oscillation wavelength difference of 10 nm or less, it is no longer necessary to precisely screen laser devices 2, saving the total cost and improving the yield. Allowing an oscillation wavelength difference of 10 nm or less also eliminates the necessity to strictly screen laser devices 2 having varying oscillation wavelengths associated with the manufacturing process and can keep failure loss low while maintaining high excitation efficiency for phosphors.

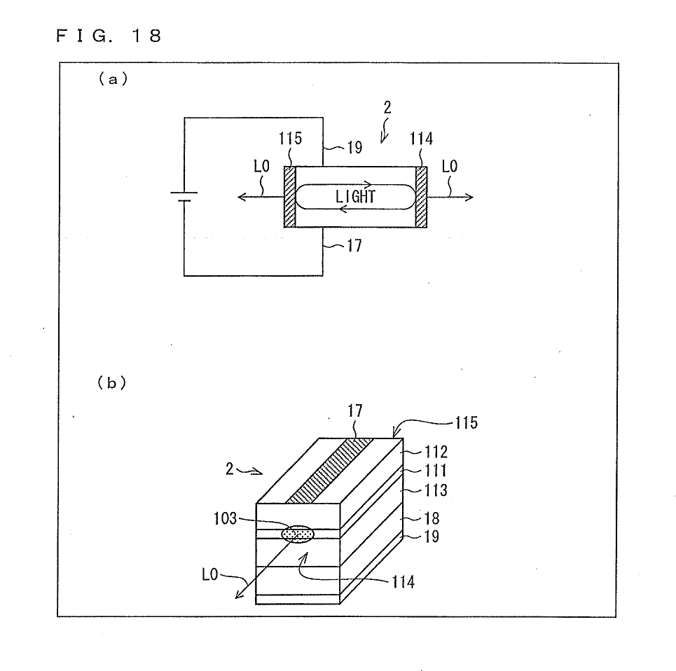

Next the basic structure of the laser device 2 is described. FIG. 18(a) is a circuit diagram of the laser device 2, while FIG. 18(b) is a perspective view showing the basic structure of the laser device 2. As shown in FIG. 18(b), the laser device 2 includes a cathode electrode 19, a substrate 18, a cladding layer 113, an active layer 111, a cladding layer 112, and an anode electrode 17 which are layered in this order.

The substrate 18 is a semiconductor substrate, typically formed from a compound semiconductor such as GaAs or GaN. The substrate 18 may also be formed from a IV semiconductor such as Si, Ge, and SiC, III-V compound semiconductor represented by GaAs, GaP, InP, AlAs, GaN, InN, InSb, GaSb, and AlN, a II-VI compound semiconductor such as ZnTe, ZeSe, ZnS, and ZnO, an oxide insulator such as ZnO, Al₂O₃, SiO₂, TiO₂, Cro₂, and CeO₂, or a nitride insulator such as SiN.

This embodiment uses GaN as the substrate 18.

The anode electrode 17 is provided for injecting electric current into the active layer 111 through the cladding layer 112.

The cathode electrode 19 is provided for injecting electric current into the active layer 111 through the cladding layer 113 from the underside of the substrate 18. Current is injected with forward bias applied to the anode electrode 17 and the cathode electrode 19.

The active layer 111 is sandwiched between the cladding layer 113 and the cladding layer 112.

The material of the active layer 111 may be any of various kinds of semiconductor, including III-V compound semiconductors represented by undoped GaAs, GaP, InP, AlAs, GaN, InN, InSb, GaSb, and AlN, or II-VI compound semiconductors such as ZnTe, ZeSe, ZnS, and ZnO.

This embodiment uses GaN and InGaN.

The active layer 111 serves to confine light amplified by stimulated emission.

On the active layer 111, a front cleavage plane 114 and a rear cleavage plane 115 are formed opposite one another for confining light amplified by stimulated emission, and the front cleavage plane 114 and the rear cleavage plane 115 serve as mirrors.

Unlike a mirror that totally reflects light, light amplified by stimulated emission exits from one of the front cleavage plane 114 and the rear cleavage plane 115 of the active layer 111 (in this embodiment, the front cleavage plane 114 for the purpose of description) upon being amplified to some degree to become excitation light L0. The active layer 111 may form a multilayer quantum well structure.

The rear cleavage plane 115, which is positioned opposite the front cleavage plane 114, has a reflective film (not shown) for laser generation formed thereon. By making a difference in the reflectances of the front cleavage plane 114 and the rear cleavage plane 115, excitation light L0 is emitted from a luminous point 103 on the end face having the lower reflectance, the front cleavage plane 114, for example.

The cladding layer 113 and the cladding layer 112 may be formed of any of semiconductors including III-V compound semiconductors represented by both n- and p-type GaAs, GaP, InP, AlAs, GaN, InN, InSb, GaSb, and AlN, or II-VI compound semiconductors such as ZnTe, ZeSe, ZnS, and ZnO. By applying forward bias to the anode electrode 17 and the cathode electrode 19, electric current can be injected into the active layer 111.

For film formation on semiconductor layers such as the cladding layer 113, cladding layer 112, and active layer 111, common film formation techniques such as metal organic chemical vapor deposition (MOCVD), molecular-beam epitaxy (MBE), chemical vapor deposition (CVD), laser ablation, and sputtering may be employed. For film formation on metal layers, common film formation techniques such as vacuum evaporation, plating, laser ablation, and sputtering may be employed.

The lens 3, provided in each laser device 2, serves to adjust (expand, for example) the irradiation range of laser light emitted by the laser device 2 so that the laser light is appropriately applied to the light emitting section 4.

The light emitting section 4 emits fluorescent light with light of the wavelength of the laser light emitted by the laser device 2, and contains phosphors that generate light upon receiving light of the wavelength of laser light. Specifically, the light emitting section 4 may be encapsulant with phosphors dispersed therein, or phosphors hardened by an appropriate treatment, e.g., pressed and heat-treated phosphors. The light emitting section 4 can be regarded as a wavelength conversion device because it converts light of the laser light wavelength to fluorescent light.

The light emitting section 4 is disposed on the metal base 7 such that the light emitting section 4 covers the focal position of the parabolic mirror 5. Accordingly, fluorescent light emitted by the light emitting section 4 reflects on the reflective curved plane of the parabolic mirror 5, so that the path of the fluorescent light is controlled.

The phosphor of the light emitting section 4 may be an oxynitride phosphor (e.g., sialon phosphor) or III-V compound semiconductor nanoparticle phosphor (e.g., indium phosphide (InP)). These phosphors have high heat and light resistance against laser light of high output power (and/or light density) emitted by the laser device 2 and thus are optimal as laser illumination light sources. The phosphor of the light emitting section 4 is not limited to the aforementioned ones but may be other kind of phosphor such as a nitride phosphor.

It is stipulated by law that the illumination light of headlamps is of a white color having a chromaticity in a prescribed range. The light emitting section 4 therefore contains phosphors selected so as to produce a white illumination light.

For example, when blue, green, and red phosphors are contained in the light emitting section 4 which is then irradiated with 405-nm laser light, white light is generated. White light is also obtained by irradiating a light emitting section 4 containing a yellow (or green or red) phosphor with laser light of 460 nm (blue) (or so-called near-blue laser light having a peak wavelength in the wavelength range from greater than 450 nm to 530 nm).

The encapsulant for the light emitting section 4 may be a glass material (inorganic glass, organic-inorganic hybrid glass) or a resin material such as silicone resin, for example. A low-melting glass may be used as glass material. The encapsulant preferably has high transparency, and for laser light of high output power, preferably has high heat and light resistance.

In place of the light emitting section 4 containing phosphors or in addition to phosphors, a scatterer which irregularly reflects and diffuses laser light may be provided near the focus of the parabolic mirror 5. The scatterer may scatter laser light received from the laser devices so that the laser light impinges on different positions on the reflecting surface of the parabolic mirror 5. Since the headlamp 1 combines plural laser devices 2 having different light wavelengths, mixing of multiple colors can easily produce white or quasi-white light.

By exciting the single light emitting section 4 with laser light emitted by multiple laser devices 2, the output power of laser light required of each laser device 2 may be reduced. This can extend the lifetime of the laser devices 2 and reduce the manufacturing costs of the laser devices 2. In addition, screening laser devices 2 that emit laser light of the same wavelength involves considerable effort and cost. By permitting the laser devices 2 to have different wavelengths, the effort and cost for screening laser devices 2 are reduced, enabling an illumination apparatus having a long life to be realized at low cost and high yield.

With the above-described configuration, the following effect is also expected. When laser light emitted by multiple laser devices 2 have the same wavelength, if the laser light outputs of the individual laser devices 2 were independently varied, composite laser light generated as the sum of laser light emitted by those laser devices 2 only undergoes a relative increase or decrease in power while maintaining its spectrum shape. Hence, (fluorescent) light emitted by the light emitting section 4 containing phosphors varies only in the luminous flux with no change in chromaticity.

In contrast, if laser devices 2 having different oscillation wavelengths are used as the laser light source, varying their laser light outputs causes a change not only in the power (light intensity) but in the spectrum shape of the resulting composite laser light. As the absorptivity and luminous efficiency of the light emitting section 4 containing phosphors vary depending on the wavelength of laser light applied thereto, varying the spectrum shape of the laser light results in change also in the spectrum of the (fluorescent) light emitted by the light emitting section 4. The above-described configuration therefore can realize an illumination apparatus that can vary the chromaticity as well as the luminous flux.

The parabolic mirror 5 reflects fluorescent light generated by the light emitting section 4 and forms a pencil of rays (illumination light) which propagates within a predetermined solid angle. The parabolic mirror 5 may be a component with metallic thin film formed on its surface or a metallic component, for example. Preferably, the component forming the surface on which illumination light is reflected has a high reflectance for the wavelength range of the illumination light in formation of a pencil of rays (illumination light) that propagates in a predetermined solid angle on the parabolic mirror.

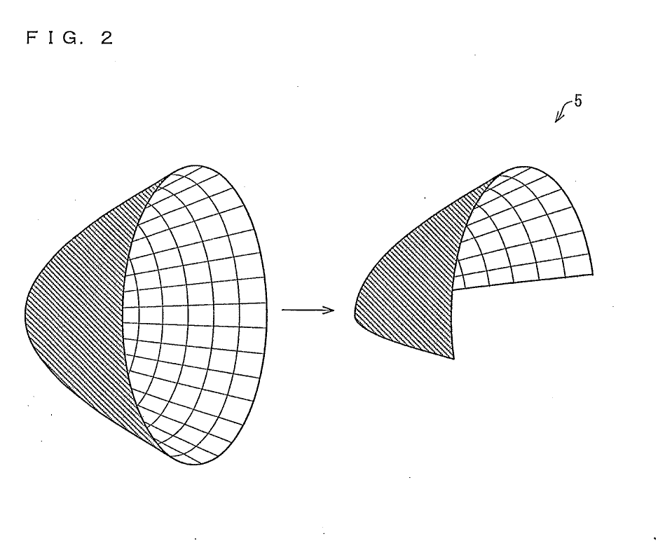

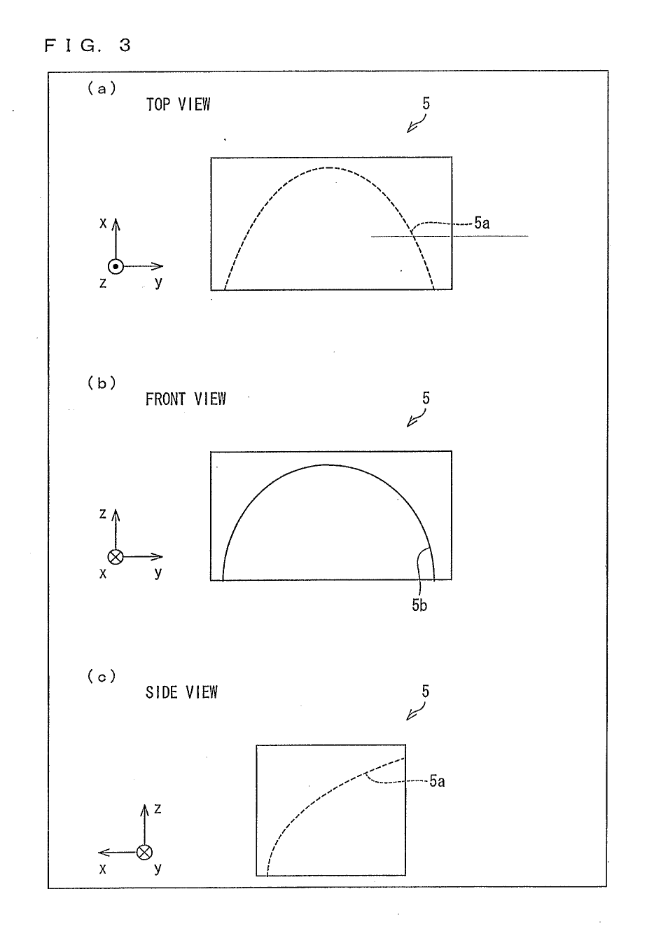

FIG. 2 is a conceptual illustration of the paraboloid of revolution of the parabolic mirror 5; FIG. 3(a) is a top view of the parabolic mirror 5; FIG. 3(b) is a front view; and FIG. 3(c) is a side view. FIGS. 3(a) to 3(c) show a parabolic mirror 5 formed by hollowing a rectangular parallelepiped material for the sake of clarity.

As illustrated in FIG. 2, the reflecting surface of the parabolic mirror 5 includes at least part of a partial curved surface formed by cutting a curved surface (a parabolic curved surface) formed by rotating a parabola about its axis of symmetry as the rotation axis, in a plane containing the rotation axis. In FIGS. 3(a) and 3(c), the curve indicated at reference character 5a represents the parabolic curved surface. As shown in FIG. 3(b), when the parabolic mirror 5 is seen from the front, its opening 5b (the exit for illumination light) is semi-circular.

The laser devices 2 are disposed outside the parabolic mirror 5, and the parabolic mirror 5 has a window 6 formed therein for transmitting or passing laser light. The window 6 may be an aperture or include a transparent material that passes light in the wavelength range of the laser light emitted by the laser devices 2 serving as the excitation light source. For example, a transparent plate equipped with a filter that passes laser light and reflects white light (fluorescent light from the light emitting section 4) may be provided as the window 6. With this arrangement, fluorescent light from the light emitting section 4 is prevented from leaking through the window 6 and fluorescent light can be utilized with high efficiency.

A single common window 6 may be provided for multiple laser devices 2 or a plurality of windows 6 may be respectively provided for the laser devices 2.

The parabolic mirror 5 may include a non-parabolic portion. Also, the reflecting mirror may be a parabolic mirror having a closed circular opening or one including a part of such a mirror. The reflecting mirror is not limited to a parabolic mirror but may be an ellipsoid or free-form surface mirror. That is, the reflecting mirror may have any shape as long as its reflecting surface includes at least part of a curved surface that is formed by rotating a certain figure (an ellipse, circle, or parabola) about a rotation axis.

The metal base 7 is a plate-like supporting component for supporting the light emitting section 4 on it and is formed of metal (e.g., copper or iron). The metal base 7 accordingly has high heat conductivity and can efficiently dissipate heat generated in the light emitting section 4. The component for supporting the light emitting section 4 is not limited to a metallic one but may be a component containing a non-metal substance that has high heat conductivity (such as ceramics). The surface of the metal base 7 that is contact with the light emitting section 4 however preferably functions as a reflecting surface. With this surface being reflective, fluorescent light converted from laser light incident from the top surface of the light emitting section 4 is reflected by the reflecting surface to be directed to the parabolic mirror 5. Alternatively, laser light incident from the top surface of the light emitting section 4 may be reflected on the reflecting surface and directed again to the inside of the light emitting section 4 to be converted to fluorescent light.

As the metal base 7 is covered by the parabolic mirror 5, the metal base 7 can be considered to have a plane facing the reflection curved surface (parabolic curved surface) of the parabolic mirror 5. Preferably, the surface of the metal base 7 on the light emitting section 4 side is approximately parallel with the rotation axis of the paraboloid of revolution of the parabolic mirror 5 and contains an almost entire portion of the rotation axis.

The fin 8 serves as a cooling section for cooling the metal base 7. The fin 8 has multiple radiator panels; its heat dissipation efficiency is enhanced by increasing the area of contact with air. The fin 8 is made of black anodized aluminum. The cooling section for cooling the metal base 7 may employ any technique capable of cooling (heat dissipation), such as heat pipe, water cooling, or air cooling.

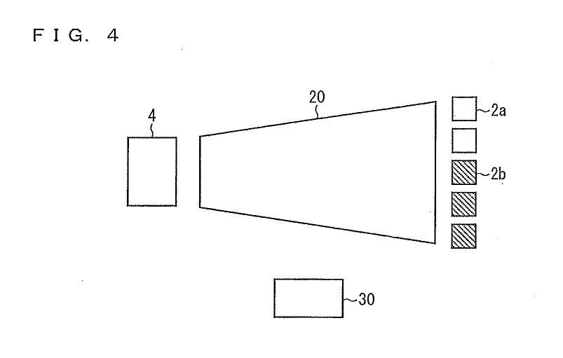

An illustrative case in which the headlamp 1 has multiple laser devices 2 is now described with reference to FIG. 4. FIG. 4 is a schematic diagram describing an example of the present embodiment. Matters already described with reference to FIG. 1 and other figures will not be repeated.

In FIG. 4, the headlamp 1 includes, at least, two laser devices 2a, three laser devices 2b, a light emitting section 4, and a tapered light guide section 20.

The tapered light guide section 20 guides laser light generated by the laser devices 2 to the light emitting section 4. The tapered light guide section 20 has an incidence end at which laser light emitted by the laser devices 2 enters the tapered light guide section 20 and an exit end at which the laser light having entered from the incidence end is emanated.

The tapered light guide section 20 has an enclosure structure defined by a light reflective side face that reflects laser light incident on the incidence end, and the cross-sectional area of the exit end of the tapered light guide section 20 is smaller than that of the incidence end.

Specifically, the entire shape of the tapered light guide section 20 is a tubular square frustum. The cross section (opening) of its exit end is a 1-by-3-mm rectangle, for example, and the cross section (opening) of its incidence end is a 15-by-15-mm rectangle, for example. The shape of the tapered light guide section 20 is not limited to a square frustum but may be any of different shapes such as polygonal frustum shapes other than a square frustum, a circular truncated cone, or an elliptic truncated cone. The length from the incidence end to the exit end may be set as appropriate.

The enclosure structure enables the tapered light guide section 20 to gather laser light incident on the incidence end to the exit end, which has a smaller cross-sectional area than the incidence end, and emanate the laser light to the light emitting section 4. The light emitting section 4 thus can be designed to be small in size even with use of multiple laser devices 2 for gaining high output power. Thus, a headlamp 1 with high output power and high luminance is realized.

The tapered light guide section 20 is formed from a transparent material such as boron-silicate crown (BK) 7, quartz glass, or acrylic resin.

In this example, laser light emitted from the two laser devices 2a and three laser devices 2b is collected to the exit end of the tapered light guide section 20 and the collected laser light is then applied to the light emitting section 4.

The headlamp 1 in Example 1 includes a light emitting section which is irradiated with laser light from the opening side of the parabolic mirror 5 (this type of light emitting section is referred to as “reflective light emitting section” in the present application), and a headlamp with a reflective light emitting section is called a reflective headlamp.

In the reflective headlamp, laser light is applied to the light emitting section 4 from the side on which the parabolic mirror 5 is disposed, causing the light emitting section 4 to emit fluorescent light in the laser light irradiation surface. The fluorescent light is then reflected off the parabolic mirror 5 to be emitted outside the headlamp.

If high output power laser light enters human eyes, it can cause damage to the eyes; laser light being reflected on the light emitting section 4 and emitted outside the illumination apparatus can be problematic. It is therefore important that laser light does not leak outside the illumination apparatus at an output power level damaging to human eyes, so an optical filter is preferably provided in the opening of the parabolic mirror 5 in terms of eye safety. Such an optical filter is capable of blocking part of light in the wavelength range of the laser light emitted from the laser device 2 and attenuating the output power of light in the wavelength range of laser light in the spectrum of illumination light released outside the illumination apparatus to a level that does not cause damage to human eyes. The optical filter is formed from a material that passes (pseudo-) white light (incoherent light) generated by conversion of laser light in the light emitting section 4. A transparent resin plate or inorganic glass plate may be employed, for example.

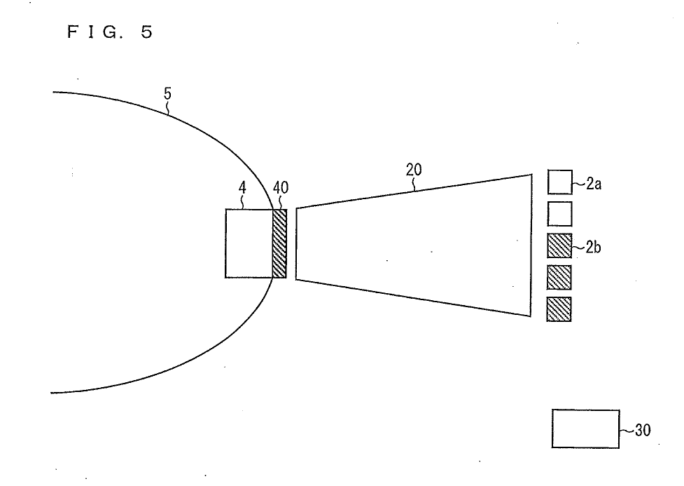

Next, an illustrative application of the configuration of FIG. 4 to a transmissive headlamp is described with FIG. 5. FIG. 5 illustrates another example which uses the configuration of FIG. 4 with a transmissive headlamp. Matters already described with reference to FIG. 1 and other figures will not be repeated.

Referring to FIG. 5, a transmissive headlamp is described first. A transmissive headlamp is a headlamp in which the light emitting section 4 is irradiated with laser light from the opposite side of the opening of the parabolic mirror 5. As illustrated, laser light emanated from the exit end of the tapered light guide section 20 passes through a transparent high thermal conductivity plate 40 and the light emitting section 4. The laser light excites phosphors contained in the light emitting section 4 as it passes through and is scattered in the light emitting section 4 to generate fluorescent light. That is, fluorescent light is generated in the light emitting section. The fluorescent light emitted from the light emitting section 4 reflects off the parabolic mirror 5 to be emitted outside the headlamp. A headlamp of this type is called a transmissive headlamp in this embodiment.

The transmissive headlamp shown in FIG. 5 includes, at least, two laser devices 2a, three laser devices 2b, a light emitting section 4, a tapered light guide section 20, a parabolic mirror 5, a setting section 30 (described in detail later), and a transparent high thermal conductivity plate 40.

The transparent high thermal conductivity plate 40 transmits light in the wavelength of the laser light emitted by the laser devices 2a and laser devices 2b. The transparent high thermal conductivity plate 40 is in contact with the light emitting section 4 and the parabolic mirror 5 on the laser light irradiation surface side of the light emitting section 4. Through the contact, the transparent high thermal conductivity plate 40 conducts heat generated in the light emitting section 4 to the parabolic mirror 5. The transparent high thermal conductivity plate 40 thereby can efficiently dissipate heat generated in the light emitting section 4, so degradation of the light emitting section 4 caused by heat is reduced. Also, as increase in the temperature of the light emitting section 4 is suppressed, the luminous efficiency of the light emitting section 4 is kept from lowering due to temperature rise.

The material of the transparent high thermal conductivity plate 40 is not limited as long as it has the above-described feature.

As described, the configuration of FIG. 4 can be effectively applied to both reflective and transmissive headlamps.

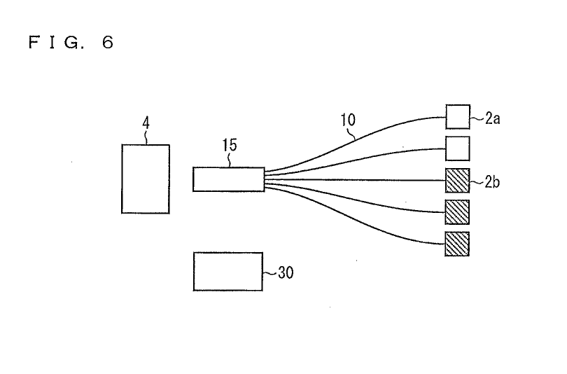

An illustrative case which the headlamp 1 has multiple laser devices 2 is described with reference to FIG. 6. FIG. 6 is a schematic diagram describing another example of the present embodiment. Matters already described with reference to FIG. 1 and other figures will not be repeated.

In FIG. 6, the headlamp 1 includes, at least, two laser devices 2a, three laser devices 2b, a light emitting section 4, optical fibers 10, and a ferrule 15.

The optical fibers 10 are pliable light guiding components for guiding laser light generated by the laser devices 2 to the light emitting section 4. The optical fibers 10 each have an incidence end at which laser light is received and an exit end at which laser light incident from the incidence end is emanated.

The optical fiber 10 has a two-layer structure in which a core is covered by a clad having a lower refractive index than the core. The core is mainly composed of quartz glass (silicon oxide) with little absorption loss of laser light, while the clad is mainly composed of quartz glass or a synthetic resin material having a lower refractive index than the core. The optical fiber 10 may be made of quartz and have a core diameter of 200 μm, a clad diameter of 240 μm, and a numerical aperture NA of 0.22, for example. The structure, thickness, and material of the optical fiber 10 are however not limited to the above, and the cross section of the optical fiber 10 vertical to the long axis direction may be a rectangle.

For the light guiding member, materials other than optical fiber or a pliable material combining optical fiber and other material may be employed. The light guiding member may have any structure that has an incidence end at which laser light generated by the laser device 2 is received and an exit end at which laser light incident from the incidence end emanates. For example, an incident portion having an incidence end and an exit portion having an exit end may be made as separate components from the optical fiber and they may be connected to the ends of the optical fiber.

The ferrule 15 retains the exit ends of the optical fibers 10 in a predetermined pattern with respect to the laser light irradiation surface of the light emitting section 4. The ferrule 15 may have holes formed in a certain pattern for inserting the exit ends of the optical fibers 10, or may be separable into an upper portion and a lower portion so that exit ends are held in grooves formed in the mating faces of the upper and lower portions.

The ferrule 15 may be fixed to the parabolic mirror 5 with a rod-shaped or tubular component extending from the parabolic mirror 5. The material of the ferrule 15 is not limited; it may be made of stainless steel, for example.

In this example, laser light emitted from the two laser devices 2a and three laser devices 2b is applied to the light emitting section 4 through the optical fibers 10 respectively connected with the laser devices 2.

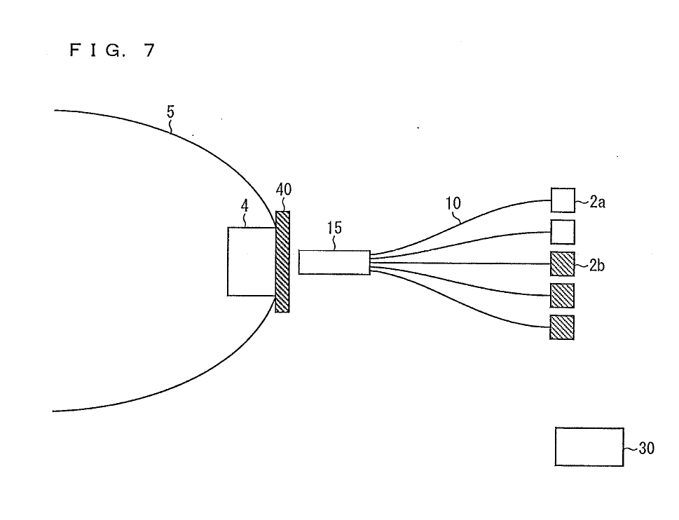

Next, an illustrative case in which the configuration of FIG. 6 is used in a transmissive headlamp is described with FIG. 7. FIG. 7 illustrates another example which uses the configuration of FIG. 6 in a transmissive headlamp.

The transmissive headlamp 1 of FIG. 7 includes, at least, two laser devices 2a, three laser devices 2b, a light emitting section 4, optical fibers 10, a ferrule 15, a parabolic mirror 5, a setting section 30 (described in detail later), and a transparent high thermal conductivity plate 40. As these components were already described with FIGS. 5 and 6, descriptions on them will not be repeated. It is however mentioned again that the configuration of FIG. 6 can be effectively applied to both reflective and transmissive headlamps.

The light emitting section 4 used in Examples 1 and 2 is formed of phosphors and encapsulant for sealing the phosphors. For the phosphors, CASN:Eu²⁺ and Caα-SiAlON:Ce³⁺ are used herein. The encapsulant is inorganic glass and its elemental composition is SiO₂—B₂O₃—CaO—BaO—Li₂O—Na₂O. The light emitting section 4 is formed of inorganic glass with phosphors dispersed in it. The weight ratio of the inorganic glass and the phosphors is: inorganic glass:(Caα-SiAlON:Ce³⁺):(CASN:Eu²⁺)=92:6:2.

The laser device 2a has an oscillation wavelength of 405 nm and the laser device 2b has an oscillation wavelength of 460 nm. For efficient application of the laser light emitted from the laser device 2a and laser device 2b to the light emitting section 4, a glass material composed of BK-7 is used as the light collection member.

In the headlamp 1 in Examples 1 and 2, the laser device 2a and the laser device 2b emit laser light of different wavelengths and vary their output power, thereby emitting illumination light of varying chromaticity to the outside. This enables the chromaticity of the headlamp 1 to be varied in response to change in weather, road conditions, or the like to gain illumination light of high visibility.

Since the laser device 2a and the laser device 2b of the headlamp 1 emit laser light of different wavelengths and are able to vary their output, the luminous flux is also adjustable in addition to the chromaticity.

As illumination light of a lower color temperature can illuminate a wider area in front of the car, this embodiment can provide a headlamp suited for illumination in bad weather such as a rainy or foggy weather.

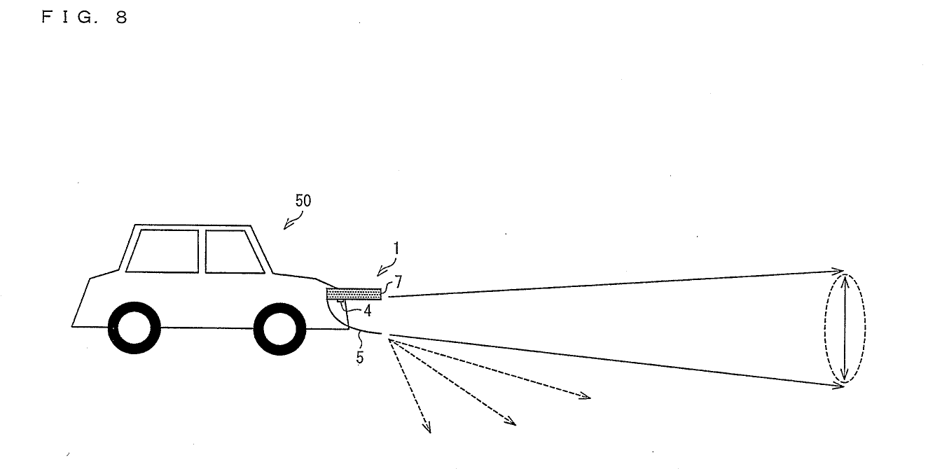

FIG. 8 schematically illustrates the orientation in which the headlamp 1 is installed when applied to a headlamp of an automobile (vehicle) 50. As shown in FIG. 8, the headlamp 1 may be installed in the head of the automobile 50 such that the parabolic mirror 5 is located on the lower side when seen vertically. In this installation, an area in front of the automobile 50 is brightly illuminated and also a lower area ahead of the automobile 50 is also moderately illuminated because of the light projection properties of the parabolic mirror 5 mentioned above.

The headlamp 1 may be employed as a driving beam headlamp (a high beam) or a passing beam headlamp (a low beam) for automobiles. During driving of the automobile 50, the light intensity distribution of laser light being applied to the irradiation surface of the light emitting section 4 may be controlled in accordance with driving conditions. Such control enables light to be projected in a desired pattern during driving of the automobile 50, providing the user with enhanced convenience.

The headlamp 1 may be applied to other kinds of illumination apparatus in addition to vehicle headlamps. A possible application of the headlamp 1 is downlight (described in detail later). A downlight is an illumination apparatus to be installed on a ceiling of a construct such as a house or vehicle. The illumination apparatus of the present invention may also implemented as a headlamp for a mobile object other than vehicles (e.g., human, ships, aircrafts, submarines, and rockets), a search light, a projector, an indoor lighting device other than a downlight (such as a floor lamp), and an outdoor lighting device.

With the above-described configuration, the headlamp 1 can solve the drawbacks of traditional headlamps. A traditional headlamp configured to vary the output power of at least two light sources having different chromaticities has luminous points as many as the light sources. Thus, such a headlamp requires complex optical design in incorporating multiple luminous points into an optical system such as a reflecting mirror or lens. Also, for realization of a high efficiency optical system for a traditional headlamp, the optical system inevitably becomes large in size.

In contrast, the headlamp 1 in the above-described embodiments permits the output power of the laser device 2a and the laser device 2b having different wavelengths to be varied. Since the absorptivity and luminous efficiency of the light emitting section 4 vary with wavelength, varying the output power of the laser device 2a and the laser device 2b having different wavelengths causes a change in wavelength components as the composite excitation light mixing the different wavelengths. Consequently, the emission spectrum (light emission intensity) of the light emitting section 4 and the spectrum shape of the excitation light that passes through (or is reflected in) the light emitting section 4 will also change. This in turn causes a change in the spectrum, namely chromaticity, of the final illumination light obtained.

Because of its structure, the headlamp 1 has only one luminous point at the light emitting section 4 and does not require change of the luminous point position. Moreover, since there is only one luminous point, only one set of an optical system to be combined with the luminous point is required, enabling reduction in the size and weight of the headlamp and facilitating the optical design for the headlamp.

The headlamp 1 may further include a setting section 30 for presetting combinations of output powers of the laser device 2a and the laser device 2b so that the light generated by the light emitting section 4 has a desired chromaticity.

The headlamp 1 may further include a setting section 30 for setting the output power of the laser device 2a and the laser device 2b so that the light generated by the light emitting section 4 falls in a desired range of a chromaticity diagram.

The setting section 30 may be implemented in any manner. As an example, an input device such as a keyboard for enabling adjustment of the output of the laser device 2a and the laser device 2b may be provided inside or outside the headlamp 1. A storage device may be also provided inside or outside the headlamp 1, and a table associating the output powers (output values) of the laser device 2a and the laser device 2b with corresponding chromaticities of illumination light to be emitted outside the headlamp 1 is stored in the storage device.

When the user wants light of a certain chromaticity, he/she inputs a number or the like corresponding to that chromaticity from the keyboard. A control section provided inside or outside the headlamp 1 then references the input and the table stored in the storage device and automatically adjusts the output power of the laser device 2a and the laser device 2b. As a result, the headlamp 1 emits light of the specified chromaticity outside the apparatus.

As another example, five or so chromaticities may be prepared for light to be emitted outside the headlamp 1 and five buttons corresponding to the chromaticities may be provided on the headlamp 1. When button A for chromaticity A is pressed, the output power of the laser device 2a and the laser device 2b are automatically adjusted so as to produce chromaticity A. When button B for chromaticity B is pressed, the output power of the laser device 2a and the laser device 2b are automatically adjusted so as to produce chromaticity B. In this manner, the headlamp 1 can emit light of a specified chromaticity outside the apparatus. The buttons may also be implemented as a touch panel provided on the headlamp 1.

As described, the setting section 30 may be implemented in different forms. Inclusion of the setting section 30 in the headlamp 1 can save the time and efforts required for repetitively adjusting the output of excitation light of different wavelengths, making the apparatus more convenient for the user.

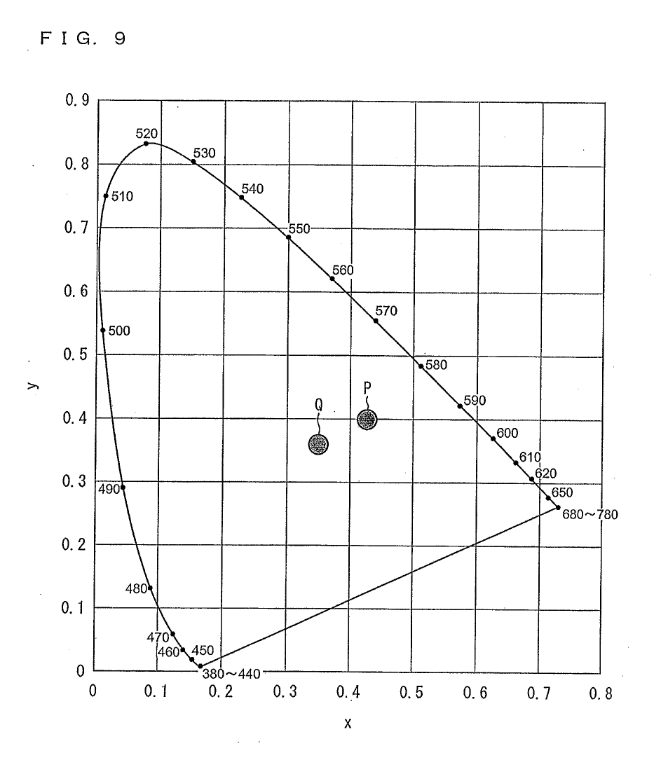

Next effects achieved by the headlamp 1 will be described with reference to FIG. 9. FIG. 9 is a chromaticity diagram for demonstrating the effects provided by the headlamp 1.

Point P in the figure indicates the chromaticity point of the fluorescent light generated by the light emitting section 4 with laser light emitted from the laser device 2a and the laser device 2b. Point Q indicates the chromaticity point after varying the output power of the laser device 2a and the laser device 2b.

In the headlamp 1, the laser device 2a and the laser device 2b emit laser light of different wavelengths and can vary their output power. Varying the output power of the laser device 2a and the laser device 2b can shift the chromaticity point of the fluorescent light generated by the light emitting section 4 from point P to Q as illustrated. The positions between which the chromaticity point shifts are not limited to points P and Q; FIG. 9 shows merely an example.

As the headlamp 1 has only one luminous point at the light emitting section, there is no need to change the luminous point position. In addition, since there is only one luminous point, only one set of an optical system to be combined with the luminous point is required, enabling reduction in the size and weight of the headlamp 1 and facilitating the optical design for the headlamp 1.

As described, the headlamp 1 is capable of easily changing illumination light properties, such as spectrum, chromaticity, and color temperature, with a simple structure.

The headlamp 1 may be configured to include a setting section for setting the output power of the excitation light sources so that the light generated by the light emitting section falls in a desired range of a chromaticity diagram.

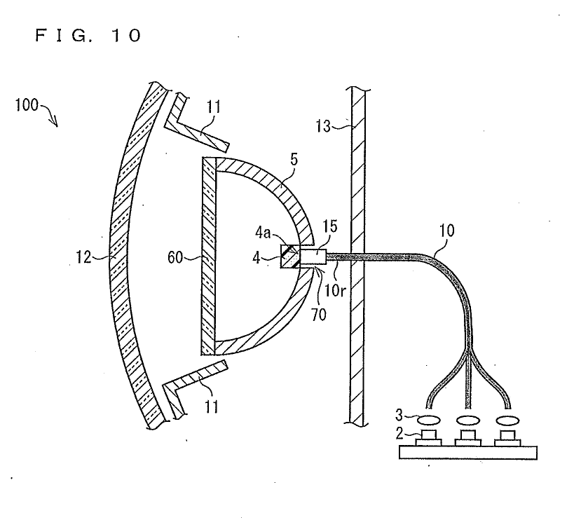

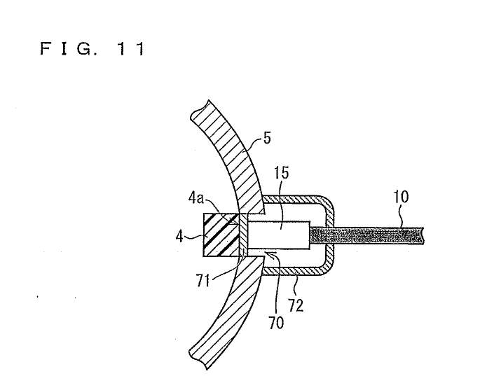

A headlamp 100 according to a further embodiment of the present invention will be described below with reference to FIGS. 10 and 11. Similar elements to those of the headlamp 100 are denoted with the same reference numerals and description of such elements is omitted. This embodiment shows a configuration in which the light emitting section 4 is held on the parabolic mirror 5. FIG. 10 is a cross-sectional view generally showing the structure of the headlamp 100 in this embodiment, and FIG. 11 illustrates the positional relation of the light emitting section 4 and the exit end 10r of the optical fiber 10.

The exit end 10r may be in contact with the laser light irradiation surface (light receiving surface) 4a as shown in FIG. 10 or disposed slightly apart from the laser light irradiation surface (light receiving surface) 4a. If the exit end 10r is disposed slightly apart from the laser light irradiation surface 4a, shock on the headlamp could hinder the laser light emanated from the exit end 10r from being properly applied to the laser light irradiation surface 4a. In that event, the laser light would exit from the parabolic mirror 5 without being converted to incoherent light in the light emitting section 4. For example, if the light emitting section 4 is provided in the optical filter 60 as mentioned above, laser light propagates through the space surrounded by the parabolic mirror 5 and the optical filter 60 (the space defined by the parabolic mirror 5 and the opening of the parabolic mirror 5) and exits from the parabolic mirror 5.

That is, when the exit end 10r is disposed slightly apart from the laser light irradiation surface 4a, coherent laser light at an output level hazardous to humans could be emitted outside (in front of) the headlamp. As the laser light emitted by the laser device 2 particularly is of high output power, it is required to prevent the laser light from being emitted outside, especially in front of, the headlamp 1.

In consideration of this, it is preferable that the exit end 10r and the laser light irradiation surface 4a are in contact with (or in the vicinity of) each other or the laser light path is covered. That is, preferably, the path of laser light formed between the exit end 10r and the laser light irradiation surface 4a when they are disposed at a distance from each other is spatially separated from the space outside the path (e.g., the space surrounded by the parabolic mirror 5 and the optical filter 60).

In FIG. 10, a hollow 70 into which the exit end 10r is inserted is formed in the bottom of the parabolic mirror 5, and the light emitting section 4 is disposed such that the center of the laser light irradiation surface 4a of the light emitting section 4 is positioned in the center of the hollow 70. A ferrule 15 for holding the exit end 10r is inserted into the hollow 70. In FIG. 10, thus the laser light irradiation surface 4a is in the proximity of the exit end 10r in the hollow 70 of the parabolic mirror 5.

The proximity of the laser light irradiation surface 4a and the exit end 10r ensures that the laser light emanated from the exit end 10r is applied to the laser light irradiation surface 4a. This can prevent laser light at an output level hazardous to humans from directly leaking to the outside without being applied to the laser light irradiation surface 4a (that is, without being converted to incoherent light) in case the headlamp 100 is subjected to some impact, for example. The headlamp 100 accordingly can provide high safety.

The laser light irradiation surface 4a and the exit end 10r do not have to be in the proximity of each other if prevention of laser light propagation in the space (region) surrounded by the parabolic mirror 5 and the optical filter 60 is contemplated. The light emitting section 4 may then be disposed such that the laser light irradiation surface 4a lies outside the space defined by the parabolic mirror 5 and the opening of the parabolic mirror 5. The expression “outside the space” is a notion including the boundary of the space and the outside of the space.

For example, in FIGS. 10 and 11, the light emitting section 4 is disposed such that the laser light irradiation surface 4a is at least on the same plane as the reflecting surface of the parabolic mirror 5 which reflects light from the light emitting section 4 (on the side facing the outside of the parabolic mirror 5, that is, outside the space). Alternatively, the light emitting section 4 itself may be provided outside the parabolic mirror 5 and inside the headlamp 100. In the latter case, the light emitting section 4 may be located in a tube (made of material that blocks laser light) which is represented by an extended hollow 70, for example. As a further alternative, part of the light emitting section 4 may be positioned inside the aforementioned space and the laser light irradiation surface 4a may be positioned outside the space (inside the hollow 70). In this case, the shape and size of the laser light irradiation surface 4a agree with the shape and size of the open area of the hollow 70.

In these arrangements, the light emitting section 4 does not receive high-power laser light inside the space. That is, laser light at an output level hazardous to humans is prevented from propagating in the space and leaking in the light irradiation direction of the headlamp 100. It also prevents direct leakage of laser light at least in the light irradiation direction in the event that laser light is not being applied to the laser light irradiation surface 4a due to some impact on the headlamp 100, for example.

While in FIG. 10 the hollow 70 is formed in the bottom of the parabolic mirror 5, this is not a limitation but it may be formed in any position on the parabolic mirror 5.

The light emitting section 4 is disposed so as to completely cover the hollow 70. This prevents laser light emanated from the exit end 10r from leaking into the region surrounded by the parabolic mirror 5 and the optical filter 60 and exiting from the opening of the parabolic mirror 5. The hollow 70 is accordingly formed to be smaller than or equal to the size of the laser light irradiation surface 4a (for a 3-by-1-mm rectangular laser light irradiation surface 4a, the open area of the hollow 70 is 3 mm² or smaller). The shape of the hollow 70 needs not necessarily be the same as the laser light irradiation surface 4a as long as the light emitting section 4 can cover the entire area of the hollow 70.

For ensuring that laser light is prevented from propagating in the space formed by the parabolic mirror 5 and the optical filter 60, it is preferable that (1) the light emitting section 4 is held not on the optical filter 60 but on the parabolic mirror 5, (2) the laser light irradiation surface 4a and the exit end 10r are close to each other, and (3) the light emitting section 4 is disposed so as to completely cover the hollow 70.

In FIG. 10, an extension 11 and a lens 12 are also illustrated. The extension 11 is provided beside the parabolic mirror 5 on the front side thereof for hiding the internal structure of the headlamp 100 to improve its appearance and also enhancing the integration of the parabolic mirror 5 into the car body. Like the parabolic mirror 5, the extension 11 is also a component with metal thin film formed on its surface. The lens 12 is disposed in the opening of the housing 13 to seal the headlamp. Light generated by the light emitting section 4 passes through the lens 12 and is emanated in front of the headlamp 100.

As depicted in FIG. 11, the light emitting section 4 and the ferrule 15 are disposed with a radiating member 71 interposed between them. That is, the laser light irradiation surface 4a and the exit end 10r are in proximity to each other across the radiating member 71.

The radiating member 71 dissipates heat generated in the light emitting section 4 due to laser light irradiation on the light emitting section 4, and is disposed in contact with the laser light irradiation surface 4a. The radiating member 71 is formed of a material that is transparent and has high heat conductivity, such as gallium nitride, magnesia (MgO), or sapphire, for example.

The radiating member 71 is a plate-like component and is disposed inside the hollow 70 so as to cover the open area of the hollow 70. The light emitting section 4 and the exit end 10r are disposed such that the laser light irradiation surface 4a is thermally coupled to one of the surfaces of the radiating member 71 (the laser light exit surface) by bonding, and the exit end 10r is in contact with or in proximity to the other surface (the laser light receiving surface).

The shape of the radiating member 71 is not limited to one that covers the open area of the hollow 70 as long as the radiating member 71 can dissipate heat generated in the light emitting section 4 into, for example, the parabolic mirror 5. The radiating member 71 may thus be a linear component including stick-like and tubular shapes extending from the parabolic mirror 5 and in contact with part of the laser light irradiation surface 4a.

For example, if the radiating member 71 is a linear component and provided only at a position away from the optical axis center (at the edge of the laser light irradiation surface 4a), it does not necessarily have to be transparent. From the viewpoint of efficiency of laser light utilization, the radiating member 71 is preferably transparent. If the radiating member 71 is tube-shaped and provided only at the edge of the laser light irradiation surface 4a, the heat dissipation effect could be further increased by feeding or circulating liquid, gas, or the like in the tube.

In general, excitation of a minute light emitting section containing phosphors with high-power excitation light (i.e., exciting the light emitting section at a high power density) poses the problem of severe degradation of the light emitting section.

A cause of degradation in the light emitting section is increase in the temperature of the irradiation region of the light emitting section irradiated with excitation light and the surrounding region (which is called a temperature rise region). When the light emitting section is irradiated with high-power excitation light (laser light) from a semiconductor laser, only the temperature rise region of the light emitting section locally becomes extremely hot, leading to the problem of rapid degradation of the region.

Accordingly, in order to prevent degradation of the light emitting section and realize a bright and long-life light source employing a configuration in which a minute light emitting section containing phosphors is excited with high-power excitation light, it is desirable to suppress increase in the temperature of the temperature rise region.

Especially when the laser light irradiation surface 4a and the exit end 10r are disposed close to each other as illustrated in FIGS. 10 and 11, there is almost no space between the laser light irradiation surface 4a and the exit end 10r, causing the irradiation region to be irradiated with stronger laser light. Consequently, heat generation in the temperature rise region of the laser light irradiation surface 4a becomes extremely large, and the light emitting section 4 can rapidly degrade due to increase in the temperature of the temperature rise region.

In the headlamp 100 shown in FIG. 11, the hollow 70 is equipped with the radiating member 71, and the exit end 10r and the light emitting section 4 are in proximity to each other across the radiating member 71. This enables heat generated in the light emitting section 4 due to laser light applied to the laser light irradiation surface 4a to be dissipated into the parabolic mirror 5 through the radiating member 71, so the life of the light emitting section 4 can be extended. If this is not a consideration, the radiating member 71 may be optional.

The headlamp 100 also includes a light blocking section 72 near the laser light irradiation surface 4a and the exit end 10r as shown in FIG. 11. The light blocking section 72 blocks at least one of laser light that has not been applied to the laser light irradiation surface 4a and laser light reflected off the laser light irradiation surface 4a, of the laser light that has been emanated from the exit end 10r. With the light blocking section 72 connected to the parabolic mirror 5, the light blocking section 72 and the parabolic mirror 5 form a sealed space that covers at least the neighborhood of the laser light irradiation surface 4a and the exit end 10r. In FIG. 11, the light blocking section 72 forms a sealed space covering the ferrule 15, laser light irradiation surface 4a, and radiating member 71. The light blocking section 72 may be made of any material that blocks the wavelengths of laser light and wavelengths in their neighborhood.

Emission of laser light in front of the headlamp 100 can be prevented by the light emitting section 4 covering the open area of the hollow 70 so as to keep laser light from leaking into the space defined by the parabolic mirror 5 and the optical filter 60, for example. In this arrangement, however, in case laser light is not appropriately applied to the laser light irradiation surface 4a due to impact on the headlamp 100, for example, laser light could leak from the hollow 70 (the junction between the light emitting section 4 and the ferrule 15). This can pose the risk of laser light at an output level hazardous to humans directly entering the user's eyes when the user opens the cover of the housing containing the headlamp 1 (the hood in the case of a car).

Provision of the light blocking section 72 can reliably prevent leakage of laser light from the hollow 70 to the outside in the event that laser light is not appropriately applied to the laser light irradiation surface 4a due to impact on the headlamp 1, for example, even if the laser light irradiation surface 4a and the exit end 10r are disposed close to each other. Also in an arrangement where the laser light irradiation surface 4a and the exit end 10r are apart from each other, laser light is prevented from exiting the space sealed by the light blocking section 72, that is, from leaking through the hollow 70 to the outside. If prevention of laser light emission at least in front of the headlamp 100 is contemplated, the light blocking section 72 needs not be necessarily provided.

In FIG. 11, the light blocking section 72 is provided for preventing laser light leakage from the hollow 70 particularly in the direction toward the outside of the parabolic mirror 5 (the direction other than the light irradiation direction). This arrangement is not a limitation, however; the light blocking section 72 may be provided also for preventing laser light emission in the light irradiation direction.

For example, the light blocking section 72 may be disposed so as to cover at least the neighborhood of the laser light path formed between the laser light irradiation surface 4a and the exit end 10r when the light emitting section 4 (laser light irradiation surface 4a) is provided inside the parabolic mirror 5. In such an arrangement, the light blocking section 72 forms a sealed space that covers at least the laser light irradiation surface 4a and the ferrule 15, and the shape of the light blocking section 72 is tubular, for example. The light blocking section 72 preferably is made of a material that blocks the wavelengths of laser light and neighboring wavelengths and passes the light emitted by the light emitting section 4.

Providing the light blocking section 72 inside the parabolic mirror 5 as described above can prevent laser light from propagating in the space defined by the parabolic mirror 5 and the optical filter 60 and exiting from the opening of the parabolic mirror 5.

Although in FIGS. 10 and 11 the sizes of the laser light irradiation surface 4a and the open area of the hollow 70 are illustrated as approximately the same, the opening may be smaller than the laser light irradiation surface 4a, in which case the edge of the laser light irradiation surface 4a may be directly coupled with the parabolic mirror 5 so that the laser light irradiation surface 4a is held by the parabolic mirror 5.

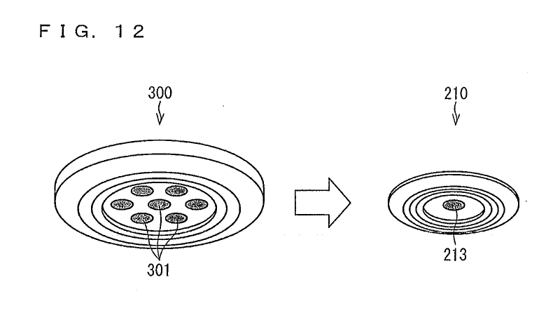

A further embodiment of the present invention will be described below with reference to FIGS. 12 to 16. Elements similar to above embodiments are denoted with the same reference numerals and description of such elements will not be repeated.

A laser downlight 200 as an example of the inventive illumination apparatus is described. The laser downlight 200 is an illumination apparatus for installation on a ceiling of a construction such as a house or a vehicle. For illumination light, the laser downlight 200 uses fluorescent light generated by irradiating the light emitting section 4 with laser light emitted from the laser device 2 or mixed light of fluorescent light generated by irradiating the light emitting section 4 with laser light emitted from the laser device 2 and light having the wavelength of the excitation light that has passed through and scattered in the light emitting section 4.

An illumination apparatus of a similar structure as the laser downlight 200 may be installed on a side wall or a floor of a construction; the place of installation for the illumination apparatus is not limited.

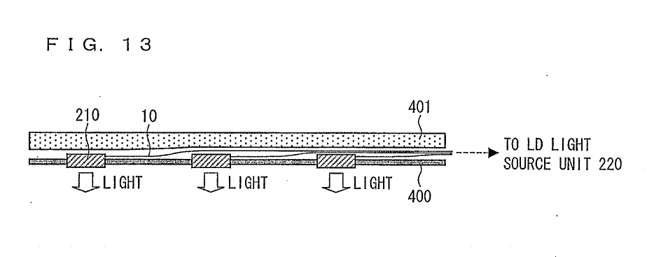

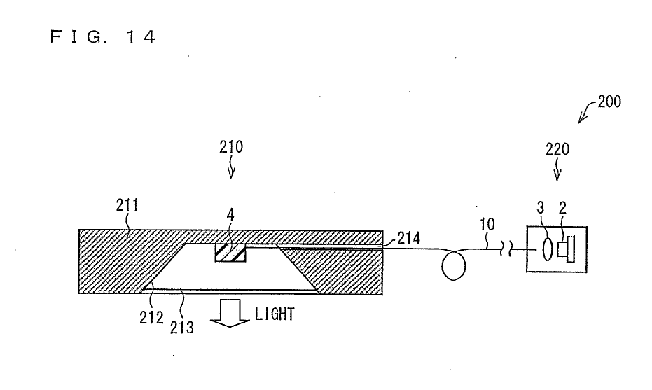

FIG. 12 schematically illustrates the appearances of a light emitting unit 210 and a traditional LED downlight 300. FIG. 13 is a cross-sectional view of a ceiling with the laser downlight 200 installed therein. FIG. 14 is a cross-sectional view of the laser downlight 200. As shown in FIGS. 12 to 14, the laser downlight 200 is buried in a ceiling board 400 and includes a light emitting unit 210 which emits illumination light and an LD light source unit 220 that feeds laser light to the light emitting unit 210 over the optical fiber 10. The LD light source unit 220 is not installed on the ceiling but disposed at a location easily accessible to the user (e.g., on a side wall in the house). Such flexibility in deciding the location of the LD light source unit 220 is enabled by connection of the LD light source unit 220 with the light emitting unit 210 over the optical fiber 10. The optical fiber 10 is disposed in a clearance between the ceiling board 400 and the heat-insulating material 401.

As shown in FIG. 14, the light emitting unit 210 includes a casing 211, an optical fiber 10, a light emitting section 4, and a light transmitting panel 213.

The casing 211 has a recessed portion 212 formed therein and the light emitting section 4 is disposed at the bottom of the recessed portion 212. On the surface of the recessed portion 212, metal thin film is formed so that the recessed portion 212 functions as a reflecting mirror.

The casing 211 also has a passage 214 formed through it for drawing the optical fiber 10, and the optical fiber 10 extends through the passage 214 to the light emitting section 4. The exit end of the optical fiber 10 and the light emitting section 4 are in a positional relation similar to the aforementioned one.

The light transmitting panel 213 is a transparent or semitransparent plate disposed so as to close the opening of the recessed portion 212. Fluorescent light from the light emitting section 4 is emitted as illumination light through the light transmitting panel 213. The light transmitting panel 213 may be removable from the casing 211 and may be omitted.

Although in FIG. 12 the light emitting unit 210 has a circular rim, there is no limitation on the shape of the light emitting unit 210 (more precisely, the shape of the casing 211).

Unlike a headlamp, for a downlight, an ideal point source of light is not required and it suffices to have a single luminous point. Accordingly, the shape, size, and placement of the light emitting section 4 are less restricted than a headlamp.

The LD light source unit 220 includes the laser device 2, the lens 3, and the optical fiber 10.

The incidence end, which is one end of the optical fiber 10, is connected to the LD light source unit 220, and laser light generated by the laser device 2 is incident on the incidence end of the optical fiber 10 through the lens 3.

Although only one set of the laser device 2 and the lens 3 is depicted in the LD light source unit 220 shown in FIG. 14, if there are two or more light emitting units 210, the bundle of optical fibers 10 respectively extending from the light emitting units 210 may be drawn to a single LD light source unit 220. In this case, a set of plural laser devices 2 and the lens 3 (or a set of plural laser devices 2 and one rod lens) is housed in one LD light source unit 220, which functions as a central power supply box.

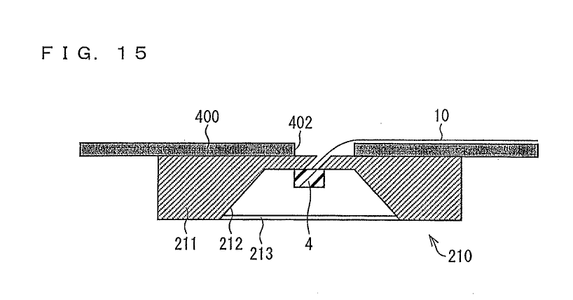

FIG. 15 is a cross-sectional view showing an alternative installation of the laser downlight 200. As shown in FIG. 15, as an alternative way to install the laser downlight 200, only a small hole 402 for inserting the optical fiber 10 may be formed in the ceiling board 400 and the laser downlight body (light emitting unit 210) may be adhered to the ceiling board 400 with strong adhesive tape or the like by taking advantage of its thinness and light weight. This way of installation has the advantages of reduced restriction relating to installation of the laser downlight 200 and significant saving of construction costs.

As shown in FIG. 12, a conventional LED downlight 300 has multiple light transmitting panels 301, from each of which illumination light is emitted. That is, the LED downlight 300 has multiple luminous points. Multiple luminous points are present in the LED downlight 300 because, since the luminous flux of light emitted by each individual luminous point is relatively small, light of a luminous flux sufficient as illumination light cannot be obtained unless multiple luminous points are provided.

In contrast, as the laser downlight 200 is an illumination apparatus with a high luminous flux, only one luminous point is sufficient. This produces the effect of formation of a clear shadow with the illumination light. In addition, use of a high color rendering phosphor (e.g., a combination of several kinds of oxynitride phosphor) for the phosphor of the light emitting section 4 can enhance the color rendering effect of the illumination light.

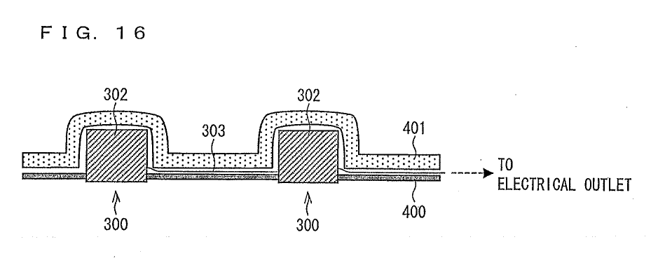

FIG. 16 is a cross-sectional view of a ceiling with the LED downlight 300 installed therein. As shown in FIG. 16, in the case of the LED downlight 300, a casing 302 containing an LED chip, a power supply, and a cooling section is buried in the ceiling board 400. The casing 302 is relatively large, and a recessed portion is formed in a heat-insulating material 401 along the contour of the casing 302 in a portion where the casing 302 is disposed. A power supply line 303 extends from the casing 302 and is connected with an electrical outlet (not shown).

This configuration poses the following problems. Firstly, since the light source (an LED chip) and the power source, which generate heat, are present between the ceiling board 400 and the heat-insulating material 401, the temperature of the ceiling increases as the LED downlight 300 is used, which causes lowering of room cooling efficiency.

Also, the LED downlight 300 requires a power source and a cooling section per light source, leading to the problem of a large total cost.

Due to the relatively large size of the casing 302, it is often difficult to install the LED downlight 300 in a clearance between the ceiling board 400 and the heat-insulating material 401.

Since the LED downlight integrally includes a metal block such as a radiating fin for dissipating heat from the LED chip, the weight of the LED downlight as a whole is heavy. This leads to the problem of requiring a dedicated casing for attachment for holding the downlight on a ceiling.

In contrast, the light emitting unit 210 of the laser downlight 200 does not contain a large heat source, so it does not decrease the room cooling efficiency. As a result, increase in room air conditioning costs can be avoided.

Since it is not necessary to provide a power source and a cooling section per light emitting unit 210, the laser downlight 200 can be compact, thin, and light. This reduces spatial restrictions on installation of the laser downlight 200 and facilitates setting in an existing house.

Additionally, as the laser downlight 200 is compact, thin, and light, the light emitting unit 210 can be installed on the surface of the ceiling board 400 as mentioned above and little space is required behind the ceiling board. Thus, the laser downlight 200 is less restricted in terms of installation than the LED downlight 300 and also enables significant savings of construction costs.

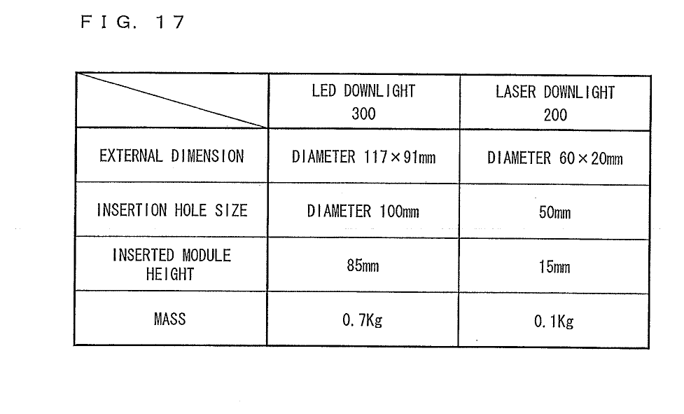

FIG. 17 is a table for comparing the specifications of the laser downlight 200 and the LED downlight 300. As shown in the figure, in an example thereof, the laser downlight 200 achieves a 94% reduction in volume and an 86% reduction in mass compared to the LED downlight 300.

Since the LD light source unit 220 can be installed at a place (height) easily accessible to the user, the laser device 2 can be easily replaced in case of a failure. In addition, drawing of optical fibers 10 extending from multiple light emitting units 210 to a single LD light source unit 220 enables central control of the multiple laser devices 2. Thus, replacement of multiple laser devices 2 is facilitated.

An LED downlight 300 using a high color rendering phosphor is able to emit a luminous flux of about 500 lm with a power consumption of 10 W, whereas a light output of 3.3 W is required for producing light of the same luminous flux with the laser downlight 200. This light output is equivalent to a power consumption of 10 W when the LD efficiency is 35% and the power consumption of the LED downlight 300 is also 10 W; there is no remarkable difference in power consumption between the two. This implies that the laser downlight 200 provides the aforementioned advantages with an equivalent power consumption to the LED downlight 300.

As described, the laser downlight 200 includes an LD light source unit 220 which has at least one laser device 2 which emits laser light, at least one light emitting unit 210 which has a light emitting section 4 and a recessed portion 212 functioning as a reflecting mirror, and optical fiber(s) 10 through which laser light is guided to the light emitting unit(s) 210.

A plurality of exit ends of the optical fibers 10 are arranged for the single light emitting section 4 included in the light emitting unit 210, and light of the strongest light intensity range in the light intensity distribution of laser light emitted from each exit end is applied to the corresponding different portion of the light emitting section 4.

This can reduce the possibility of the light emitting section 4 becoming significantly degraded due to concentrated irradiation of laser light at a single spot on the light emitting section 4 in the laser downlight 200. Consequently, the laser downlight 200 can have a long life.

The laser downlight 200 also achieves the following effect.

Despite a single luminous point, the laser downlight 200 can vary the chromaticity of illumination light just by varying the laser light output. The laser downlight 200 therefore is able to vary the chromaticity of illumination light emitted by the single luminous point without requiring manual and physical replacement of the light emitting section and without providing a complicated mechanism near the light emitting section, such as a mechanism for varying the chromaticity of illumination light emitted from the light emitting section 4 by use of a mechanical driving means for physically changing the light emitting section 4 or a filter, or a mechanism that has light sources for emitting light of different colors and turns on and off the light sources to vary the chromaticity of illumination light. The laser downlight 200 therefore provides the effect of illumination light forming a clear shadow because there is only one luminous point while allowing chromaticity adjustment according to activity (e.g., having a meal, watching TV, or family gathering), time (e.g., morning, daytime, and night), or mood (e.g., wanting to relax).

To solve the problems described above, an illumination apparatus according to an embodiment of the invention may include a plurality of excitation light sources that emit excitation light, and a light emitting section that generates light upon receiving the excitation light emitted by the excitation light sources, wherein the excitation light sources may emit excitation light of different wavelengths and are be able to vary the output power of the excitation light.

In general, the absorptivity and luminous efficiency of the light emitting section of an illumination apparatus vary depending on the wavelength of the excitation light applied to it. Thus, when the output power of individual excitation light sources having different wavelengths is varied as in the above-described illumination apparatus, the spectrum of excitation light becomes the sum of different wavelengths of light, that is, has a spectrum shape with multiple sharp peaks rather than a spectrum with a single peak wavelength such as found with traditional LEDs. Accordingly, from a macroscopic perspective, the wavelength components of light generated by the light emitting section vary. That is, the emission spectrum (emission intensity) of the light emitting section and the spectrum shape of excitation light that passes through (or reflects in) the light emitting section change. This can vary the spectrum, namely chromaticity, of the final illumination light obtained. Spectrum as described herein refers to the wavelength dependency of emission intensity, and change in the spectrum shape means change in emission intensity or change in chromaticity.

In this respect, in the illumination apparatus according to an embodiment of the invention, the excitation light sources emit excitation light of different wavelengths and their output power is varied, thereby enabling emission of illumination light having a varying spectrum shape, that is, varying chromaticity. Due to its structure, there is only one luminous point at the light emitting section and there is no need to change the luminous point position. In addition, since there is only one luminous point, only one set of an optical system to be combined with the luminous point is required, enabling reduction in the size and weight of the illumination apparatus and facilitating the optical design for the illumination apparatus.

According to an embodiment of the illumination apparatus of the invention, illumination light to be emitted outside the illumination apparatus may be composed of light generated by the light emitting section and excitation light of the plurality of different wavelengths, and the output power of excitation light of the plurality of different wavelengths may be greater than zero.

According to an embodiment of the illumination apparatus of the invention, illumination light emitted outside the illumination apparatus is composed of light generated by the light emitting section and the excitation light of different wavelengths (that have passed through or reflected in the light emitting section). The output power of the excitation light of different wavelengths is greater than zero and the wavelengths of the excitation light sources are different from each other.

Thus, the illumination apparatus in an embodiment of the invention is able to generate illumination light of varying chromaticity by changing the excitation light output power that is greater than zero.

The illumination apparatus according to an embodiment of the invention may include a setting section for presetting combinations of output powers of the excitation light sources so that the light generated in the light emitting section has a desired chromaticity.

Repetitively adjusting the output power of excitation light having different wavelengths for gaining light of a desired chromaticity from an illumination apparatus takes time and effort and significantly impairs the user's convenience.

In this respect, the illumination apparatus according to an embodiment of the invention includes a setting section for presetting combinations of output powers of the excitation light sources such that the light generated in the light emitting section has a desired chromaticity. Presetting in the setting section enables the user to gain light of a desired chromaticity from the illumination apparatus without expenditure of time and effort, enhancing the user's convenience.

The illumination apparatus according to an embodiment of the invention may include a setting section for setting the output powers of the excitation light sources such that light generated in the light emitting section falls within a desired range of a chromaticity diagram.

Repetitively adjusting the output power of excitation light having different wavelengths so that light generated in the light emitting section falls within a desired range of a chromaticity diagram takes time and effort and significantly impairs the user's convenience.

In this respect, the illumination apparatus according to an embodiment of the invention includes a setting section for setting the output powers of the excitation light sources so that light generated in the light emitting section falls within a desired range of a chromaticity diagram. Presetting in the setting section enables adjustment to make light generated in the light emitting section fall in a desired range of a chromaticity diagram without expenditure of time and effort, enhancing the user's convenience.

The illumination apparatus according to an embodiment of the invention may include a light guide section for guiding excitation light emitted by the excitation light sources, wherein the light guide section may collect the excitation light being guided into the light emitting section.

In this configuration, the excitation light sources and the light emitting section can be disposed at a distance from each other, so that heat generated in the excitation light sources and the light emitting section can be dispersed.

Interposing of the light guide section also increases the flexibility in installation location (or layout) for the excitation light sources and the light emitting section. This in turn yields the advantage of increased flexibility of design for the illumination apparatus according to an embodiment of the invention and an apparatus incorporating the illumination apparatus themselves.

The illumination apparatus according to an embodiment of the invention may include a light guide section for guiding excitation light emitted by the excitation light sources, wherein the light guide section may have plural optical fibers on which excitation light is respectively received from the excitation light sources, and the excitation light exit ends of the optical fibers may be bundled.

Optical fiber is pliable and its length can be easily adjusted. Thus, the aforementioned configuration permits the positions of the excitation light sources to be freely changed, that is, the flexibility in installation location (layout) for the excitation light sources is increased in relation to guiding of excitation light generated by the excitation light sources to the light emitting section.

Further, by bundling the excitation light exit ends of the optical fibers, all the exit end of the optical fibers can be stably disposed near the light emitting section. Bundling of the optical fibers also enables the exit ends to be gathered in one place, contributing to making the illumination apparatus compact. Moreover, bundling the optical fibers enables the light emitting section to be stably irradiated with excitation light, so an illumination apparatus capable of maintaining stable light distribution can be provided to users.

In the illumination apparatus according to an embodiment of the invention, the light emitting section may contain phosphors that emit fluorescent light upon receiving the excitation light.

In this configuration, excitation light emitted by the excitation light sources is converted to fluorescent light by the phosphors contained in the light emitting section. The fluorescent light and excitation light of different wavelengths that has passed through or reflected in the light emitting section are then combined to be emitted as illumination light outside the illumination apparatus. The illumination apparatus according to an embodiment of the invention can thereby easily emit illumination light of a varying spectrum shape, that is, varying chromaticity, by varying the output power of the excitation light having different wavelengths.

As described, the illumination apparatus according to an embodiment of the invention can also effectively realize a configuration in which the light emitting section contains phosphors that generate fluorescent light with excitation light.

In the illumination apparatus according to an embodiment of the invention, the light emitting section may contain a scatterer for scattering the excitation light.

In this configuration, excitation light emitted by the excitation light sources is scattered by the scatterer contained in the light emitting section and the resulting scattered light and the excitation light of different wavelengths that has passed through or reflected in the light emitting section are combined to be emitted as illumination light outside the illumination apparatus. The illumination apparatus according to an embodiment of the invention can thereby easily emit illumination light of a varying spectrum shape, that is, varying chromaticity, by varying the output power of the excitation light having different wavelengths.

The illumination apparatus according to an embodiment of the invention thus can effectively realize a configuration in which the light emitting section contains a scatterer for scattering excitation light.

In an embodiment of the illumination apparatus according to the invention, the light emitting section may have a light receiving surface on which excitation light emitted from the excitation light sources is received, and the light receiving surface may be positioned outside the space formed by a reflecting mirror, which reflects light emitted by the light emitting section to form a pencil of rays that propagates within a predetermined solid angle, and the opening of the reflecting mirror.

In this configuration, since the light receiving surface lies outside the space formed by the reflecting mirror and the opening of the reflecting mirror (the space surrounded by the reflecting mirror and the opening of the reflecting mirror), no excitation light (high output power excitation light in particular, e.g., laser light) will be received inside the space. This prevents excitation light at an output level hazardous to humans from propagating through the space and leaking to the outside (at least in the irradiation direction of light emitted from the light emitting section).

This also prevents direct leakage of excitation light at least in the light irradiation direction in the event that excitation light is not applied to the light receiving surface due to some impact on the illumination apparatus, for example.

As described, by disposing the light emitting section with its light receiving surface positioned outside the space, a highly safe illumination apparatus can be realized.

In the illumination apparatus according to an embodiment of the invention, the light emitting section may have a light receiving surface on which excitation light emitted from the light guide section is received, and the light guide section may have an exit end at which the excitation light received from the excitation light sources is emanated to the light emitting section, and a light blocking section may be provided in the vicinity of the light receiving surface and the exit end for blocking at least one of excitation light that has not been applied to the light receiving surface and excitation light reflected off the light receiving surface, of excitation light that has emerged from the exit end.

In this configuration, due to inclusion of the light blocking section, the illumination apparatus according to an embodiment of the invention can reliably prevent leakage of excitation light to the outside in the event that excitation light is not appropriately applied to the light receiving surface due to impact on the illumination apparatus for example. In this configuration, since no excitation light propagates through the space formed by the reflecting mirror and the opening of the reflecting mirror, emission of excitation light in the light irradiation direction as well as leakage in other directions are prevented.

In the illumination apparatus according to an embodiment of the invention, the light emitting section may have a light receiving surface on which excitation light emitted from the light guide section is received, the light guide section may have an exit end at which the excitation light received from the excitation light sources is emanated to the light emitting section, and the light receiving surface and the exit end may be in proximity to each other.

In this configuration, the light receiving surface of the light emitting section is in proximity to the exit end of the light guide section, so no excitation light (high output power excitation light in particular) will propagate through the space formed by the reflecting mirror and the opening of the reflecting mirror. This can prevent excitation light at an output level hazardous to humans from directly leaking to the outside without being applied to the light receiving surface when the illumination apparatus is subjected to some impact, for example. A highly safe illumination apparatus can therefore be realized.

The illumination apparatus according to an embodiment of the invention may further include a reflecting mirror which reflects light emitted by the light emitting section to form a pencil of rays that propagates within a predetermined solid angle, and the reflecting mirror may have a hollow into which the exit end is inserted, the hollow may have a radiating member therein that dissipates heat generated in the light emitting section due to excitation light irradiation on the light emitting section, and the light receiving surface and the exit end may be in proximity to each other across the radiating member.

As the light receiving surface is closer to the exit end, more heat is generated in the light emitting section (the temperature of the light emitting section increases), possibly causing rapid deterioration of the light emitting section.

In this configuration, a radiating member is provided in a hollow of the reflecting mirror, and the exit end and the light receiving surface are in proximity to each other across the radiating member. This enables heat generated in the light emitting section due to excitation light applied to the light receiving surface to be dissipated into the reflecting mirror through the radiating member, so the life of the light emitting section can be extended.

Accordingly, even if the light receiving surface and the exit end are disposed close to each other for ensuring safety, temperature rise in the light emitting section can be suppressed. Accordingly, a highly safe and long-life illumination apparatus can be realized.

In the illumination apparatus according to an embodiment of the invention, the plurality of laser light sources may contain GaN, InN, and a mixed crystal compound thereof and have oscillation wavelengths from 400 nm to 420 nm, and the difference in the oscillation wavelengths may be 10 nm or less.

This configuration can enhance the power conversion efficiency of the laser light sources and hence the illumination apparatus can have an increased luminous efficiency. With the oscillation wavelength of the laser light source in the range from 400 nm to 420 nm, many phosphors are efficiently excited with light in this wavelength range. Phosphors that emit blue light in particular are excited with light of this wavelength range with a high degree of efficiency. Accordingly, the total luminous efficiency of the illumination apparatus can be increased.

In the illumination apparatus according to an embodiment of the invention, the plurality of laser light sources may have oscillation wavelengths greater than 450 nm and 530 nm or less and the difference in the oscillation wavelengths may be 10 nm or less.

This configuration can increase the safety for retinas of laser light contained in the illumination light emitted by the illumination apparatus. Accordingly the emission limit at which eye safety is assured becomes higher than when phosphors are excited with 450-nm laser light, which in turn enables setting of high light output for the laser light which excites phosphors. The illumination apparatus can thereby emit higher output power illumination light.

Making multiple laser light sources have an identical oscillation wavelength requires precise screening. As laser light sources typically have slightly different oscillation wavelengths, preparation of laser light sources with the same oscillation wavelength is very expensive and leads to low yield. Since an oscillation wavelength difference of 10 nm or less is allowed in the configuration of the present invention, it is no longer necessary to precisely screen laser light sources, saving the total cost and improving the yield. Allowing an oscillation wavelength difference of 10 nm or less also eliminates the necessity to strictly screen laser light sources having varying oscillation wavelengths associated with the manufacturing process and can keep failure loss low while maintaining high excitation efficiency for phosphors.

A vehicle headlamp according to an embodiment of the invention may include any one illumination apparatus described above.

The illumination apparatus according to an embodiment of the invention can be effectively applied to a vehicle headlamp. Application of the illumination apparatus according to an embodiment of the invention to a vehicle headlamp, for example, can realize a vehicle headlamp that can emit illumination light of varying chromaticity without changing the luminous point position, easily solving the challenges of existing techniques.

A downlight according to an embodiment of the invention may include any one illumination apparatus described above.

As mentioned above, in the illumination apparatus according to an embodiment of the invention, the excitation light sources emit excitation light of different wavelengths and their outputs are varied, thereby enabling emission of illumination light having a varying spectrum shape, that is, varying chromaticity.

Thus, a downlight employing the illumination apparatus according to an embodiment of the invention is able to vary the chromaticity of illumination light just by varying the excitation light output. The downlight therefore can vary the chromaticity without requiring manual and physical replacement of the light emitting section and without providing a complicated mechanism near the light emitting section, such as a mechanism for varying the chromaticity of illumination light emitted from the light emitting section by use of a mechanical driving means for physically changing the light emitting section or a filter, or a mechanism that has light sources for emitting light of different colors and turns on and off the light sources to vary the chromaticity of illumination light.

By comparison, many of traditional downlights are designed to use plural LEDs having different chromaticities and vary the output power of the LEDs so as to achieve a desired chromaticity. A traditional downlight thus has many luminous points and requires a large optical system. As another scheme, they can employ a configuration in which a filter is mechanically mounted to the light source to vary the chromaticity. The latter scheme however poses the problem of requiring a mechanical driving means.

In this respect, the downlight according to an embodiment of the invention has only one luminous point and therefore it can freely vary the chromaticity just by electrically varying the way of driving the light sources even for a small optical system, thus solving the problem of traditional downlights.

As described, the illumination apparatus according to an embodiment of the invention includes a plurality of excitation light sources that emit excitation light, and a light emitting section that generates light upon receiving excitation light emitted by the plurality of excitation light sources, wherein the plurality of excitation light sources emit excitation light of different wavelengths and are able to vary their output power.

The illumination apparatus therefore has the advantage of being able to emit illumination light of varying chromaticity without changing the luminous point position.

The present invention is not limited to the above-described embodiments but various modifications are possible within the scope of claims. An embodiment obtained by combining technical means disclosed in different embodiments is also encompassed in the technical scope of the invention.

The present invention is applicable as an illumination apparatus that can emit illumination light of varying chromaticity without changing the luminous point position, and can be effectively employed in vehicle headlamps and downlights in particular.

### REFERENCE SIGNS LIST

1 headlamp (illumination apparatus)
2 laser device (excitation light source)
3 lens (excitation light)
4 light emitting section
5 parabolic mirror
7 metal base
8 fin
10 optical fiber (light guide section)
15 ferrule
30 setting section
40 transparent high thermal conductivity plate
50 automobile (vehicle)
60 optical filter
70 hollow
71 radiating member
72 light blocking section
20 tapered light guide section
30 setting section
200 laser downlight
210 light emitting unit
211 casing
212 recessed portion
213 light transmitting panel
214 passage
220 light source unit
300 LED downlight
301 light transmitting panel
302 casing
303 power supply line
400 ceiling board
401 heat-insulating material

1. An illumination apparatus comprising:
a plurality of laser light sources that emit laser light; and
a light emitting section that generates light upon receiving light; wherein
the plurality of laser light sources generate laser light of a plurality of wavelengths different from one another and each generate laser light of a wavelength that causes the light emitting section to generate light, and
the one light emitting section is irradiated with laser light from the plurality of laser light sources.

2. The illumination apparatus according to claim 1, wherein the plurality of laser light sources are capable of varying their output power.

3. The illumination apparatus according to claim 1, wherein
illumination light to be emitted outside the illumination apparatus is composed of light generated by the light emitting section and laser light of the plurality of different wavelengths, and
the output power of laser light of the plurality of different wavelengths is greater than zero.

4. The illumination apparatus according to claim 1, further comprising:
a setting section that presets combinations of output powers of the plurality of laser light sources such that the light generated in the light emitting section has a desired chromaticity.

5. The illumination apparatus according to claim 1, further comprising:
a setting section that sets the output powers of the plurality of laser light sources such that light generated in the light emitting section falls within a desired range of a chromaticity diagram.

6. The illumination apparatus according to claim 1, further comprising:
a light guide section for guiding laser light emitted by the plurality of laser light sources; wherein
the light guide section collects the laser light being guided into the light emitting section.

7. The illumination apparatus according to claim 1, further comprising:
a light guide section for guiding laser light emitted by the plurality of laser light sources; wherein
the light guide section has a plurality of optical fibers on which laser light is respectively received from the plurality of laser light sources, and
laser light exit ends of the plurality of optical fibers are bundled.

8. The illumination apparatus according to claim 1, wherein the light emitting section contains phosphors that emit fluorescent light upon receiving the laser light.

9. The illumination apparatus according to claim 1, wherein the light emitting section contains a scatterer for scattering the laser light.

10. The illumination apparatus according to claim 1, wherein the light emitting section has a light receiving surface on which laser light emitted from the laser light sources is received, and the light receiving surface is positioned outside a space formed by a reflecting mirror which reflects light emitted by the light emitting section to form a pencil of rays that propagates within a predetermined solid angle and an opening of the reflecting mirror.

11. The illumination apparatus according to claim 6,
the light emitting section has a light receiving surface on which laser light emanated from the light guide section is received,
the light guide section has an exit end at which the laser light received from the laser light sources is emanated to the light emitting section, and
a light blocking section is provided in vicinity of the light receiving surface and the exit end for blocking at least one of laser light that has not been applied to the light receiving surface and laser light reflected off the light receiving surface, of laser light that has been emanated from the exit end.

12. The illumination apparatus according to claim 6, wherein
the light emitting section has a light receiving surface on which laser light emanated from the light guide section is received,
the light guide section has an exit end at which the laser light received from the laser light sources is emanated to the light emitting section, and
the light receiving surface and the exit end are in proximity to each other.

13. The illumination apparatus according to claim 11, further comprising:
a reflecting mirror which reflects light emitted by the light emitting section to form a pencil of rays that propagates within a predetermined solid angle; wherein
the reflecting mirror has a hollow into which the exit end is inserted,
the hollow has a radiating member therein that dissipates heat generated in the light emitting section due to laser light irradiation on the light emitting section, and
the light receiving surface and the exit end are in proximity to each other across the radiating member.

14. The illumination apparatus according to claim 1, wherein the plurality of laser light sources contain GaN, InN, and a mixed crystal compound thereof and have oscillation wavelengths from 400 nm to 420 nm, and a difference in the oscillation wavelengths is 10 nm or less.

15. The illumination apparatus according to claim 1, wherein the plurality of laser light sources have oscillation wavelengths greater than 450 nm and 530 nm or less and the difference in the oscillation wavelengths is 10 nm or less.

16. A vehicle headlamp comprising the illumination apparatus according to claim 1.

17. A downlight comprising the illumination apparatus according to claim 1.
